(19) United States
(12) Patent Application Publication
(10) Pub. No.: US 2026/0346399 A1
(43) Pub. Date: Nov. 5, 2026

(54) TOP RING AND APPARATUS FOR PROCESSING SUBSTRATE

(71) Applicant: EBARA CORPORATION, Tokyo (JP)

(72) Inventor: Makoto KASHIWAGI, Tokyo (JP)

(21) Appl. No.: 19/119,723

(22) PCT Filed: Oct. 3, 2023
(86) PCT No.: PCT/JP2023/036057

§ 371 Date: Apr. 9, 2025

(30) Foreign Application Priority Data
Oct. 13, 2022 (JP) 2022-164921

(51) Int. Cl. B24B 37/32; B24B 37/04; H10P 72/00

(52) U.S. Cl. CPC B24B 37/32; B24B 37/04; H10P 72/0428

(57) ABSTRACT

An object is to provide a top ring that is configured to improve the uniformity of polishing. There is provided a top ring configured to hold a substrate, comprising: a base member connected with a rotating shaft; a substrate suction member including a porous member that has a substrate suction face configured to suck the substrate thereon and a decompression portion configured to communicate with a decompression unit; and a first pressurization assembly placed between the base member and the substrate suction member and provided with a plurality of first pressurization units, which are placed on an opposite side of the substrate suction member that is opposite to the substrate suction face, wherein each of the first pressurization units is configured to apply a pressing force fully independently of each other to the substrate suction member.

### TECHNICAL FIELD

The present disclosure relates to a top ring and an apparatus for processing a substrate.

### BACKGROUND ART

A chemical mechanical polishing (CMP) apparatus for flattening the surface of a substrate is used to manufacture semiconductor devices. In many cases, substrates used for manufacturing semiconductor devices are in a disk shape. A demand for high flatness has been grown in the case of flattening the surface of a quadrilateral (rectangular) substrate, for example, a CCL (Copper Clad Laminate) substrate, a PCB (Printed Circuit Board) substrate, a photomask substrate, or a display panel, as well as the substrate of the semiconductor device. Moreover, a demand for flattening the surface of a package substrate with electronic devices placed thereon, such as the PCB substrate, has also been grown.

A substrate processing apparatus, such as a chemical mechanical polishing apparatus, includes, for example, a top ring configured to hold a substrate. This top ring holds a substrate WF by means of vacuum suction using a substrate suction member. While the top ring in this state is rotated, the substrate WF is pressed against a polishing pad on a polishing table that is also rotated, so as to be processed by chemical mechanical polishing.

Furthermore, in some cases, a plurality of piezoelectric elements are placed in the top ring, in order to regulate a pressure force (pressing force) of pressing the substrate against the polishing pad by the top ring (as described in Japanese Unexamined Patent Publication No. H09-225820 (PTL 1) and in Japanese Unexamined Patent Publication No. 2000-094301 (PTL 2)).

### CITATION LIST

### Patent Literatures

PTL 1: Japanese Unexamined Patent Publication No. H09-225820
PTL 2: Japanese Unexamined Patent Publication No. 2000-094301

### SUMMARY OF INVENTION

### Technical Problem

The polishing apparatus described above is likely to have a problem of unevenness of polishing on a surface of the substrate to be polished, due to an unevenness in thickness of the substrate and a variation in in-plane uniformity of a porous member/a shielding member configuring a substrate suction portion of the top ring. For example, the porous member is subjected to a flattening (milling) process using a flattening/milling blade, in order to achieve the flatness (uniformity in thickness). A machining mark of such flattening or milling may be transferred directly to a polishing rate.

In the case of a plane cutting process using a milling cutter, there is a difficulty in achieving a high accuracy of flatness and/or thickness on a substrate suction face of the porous member to such a level that does not affect the polishing performance. In order to increase the accuracy to such a level that does not affect the polishing performance, there is a need to select a processing method of a higher accuracy. This, however, increases the cost. Moreover, unlike the semiconductor wafer, the rectangular substrate characteristically tends to have a large variation in thickness. Such a large variation in thickness is likely to significantly affect the polishing.

With a view to improving the in-plane uniformity of the polishing rate, the top ring may be provided with a plurality of compression chambers that are parted from each other by an elastic membrane. The configuration of making a difference in pressure between the respective compression chambers is able to correct the uniformity of a force of pressing a substrate to some extent. It is, however, very difficult to make a minute and complicated pressure difference. Even if it is possible to make such a minute and complicated pressure difference, this requires an expensive configuration. Furthermore, once a design is settled, significant labor is required for a change in design. There is also still a room in improving the in-plane uniformity of the polishing rate in the top ring provided with a plurality of piezoelectric elements (as described in Japanese Unexamined Patent Publication No. H09-225820 (PTL 1) and in Japanese Unexamined Patent Publication No. 2000-094301 (PTL 2)).

One object of the present disclosure is to provide a top ring that is configured to improve the uniformity of polishing.

### Solution to Problem

According to one aspect of the present disclosure, there is disclosed atop ring configured to hold a substrate, comprising: a base member connected with a rotating shaft; a substrate suction member including a porous member that has a substrate suction face configured to suck the substrate thereon and a decompression portion configured to communicate with a decompression unit; and a first pressurization assembly placed between the base member and the substrate suction member and provided with a plurality of first pressurization units, which are placed on an opposite side of the substrate suction member that is opposite to the substrate suction face, wherein each of the first pressurization units is configured to apply a pressing force fully independently of each other to the substrate suction member.

### BRIEF DESCRIPTION OF DRAWINGS

FIG. 1 is a plan view illustrating the general configuration of a substrate processing apparatus according to one embodiment;

FIG. 2 is a perspective view schematically illustrating the configuration of a polishing unit according to one embodiment:

FIG. 3 is a sectional view schematically illustrating a top ring according to one embodiment:

FIG. 4 is a sectional view schematically illustrating the top ring according to the embodiment;

FIG. 5 is a sectional view taken along a line k-k in FIG. 3;

FIG. 6 is a sectional view taken along a line m-m in FIG. 3;

FIG. 7 is a diagram illustrating a modification of a frame member of a substrate suction member:

FIG. 8 is an explanatory diagram illustrating one example of a calibration method of the top ring;

FIG. 9 is an explanatory diagram illustrating another example of the calibration method of the top ring; and

FIG. 10 is a flowchart of calibration.

### DESCRIPTION OF EMBODIMENTS

The following describes embodiments of the top ring and the apparatus for processing a substrate according to the present disclosure with reference to the attached drawings. In the attached drawings, identical or similar elements or components are represented by identical or similar reference signs. In the description of the respective embodiments, duplicated explanation about the identical or similar elements or components may be omitted. The characteristics and the features expressed in each of the embodiments are applicable to the other embodiments, unless they contradict each other.

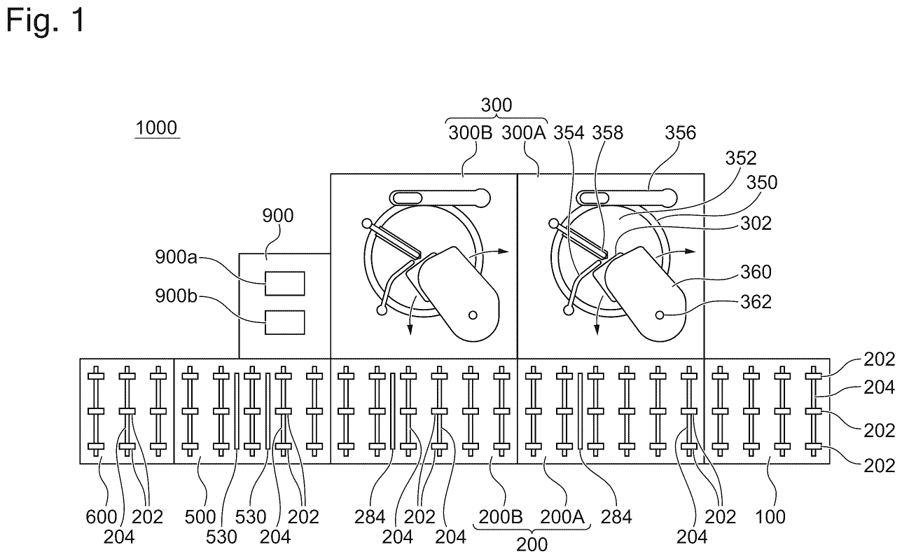

FIG. 1 is a plan view illustrating the general configuration of a substrate processing apparatus 1000 according to one embodiment. The substrate processing apparatus 1000 shown in FIG. 1 includes a loading unit 100, a transfer unit 200, a polishing unit 300, a drying unit 500, and an unloading unit 600. In the illustrated embodiment, the transfer unit 200 includes two transfer units 200A and 200B, and the polishing unit 300 includes two polishing units 300A and 300B. According to one embodiment, these respective units may be formed independently. Independently forming these units enables the substrate processing apparatus 1000 of different configurations to be readily formed by combining arbitrary numbers of the respective units. The substrate processing apparatus 1000 also includes a controller 900. The respective components of the substrate processing apparatus 1000 are controlled by the controller 900. According to one embodiment, the controller 900 may be configured by a general computer including, for example, an input-output device, an arithmetic device 900a and a storage device 900b. The arithmetic device 900a may include a CPU, an MPU or the like. The storage device 900b may include any arbitrary non-volatile memory and/or arbitrary volatile memory.

### <Loading Unit>

The loading unit 100 is a unit configured to introduce a substrate WF prior to processing, such as polishing and cleaning, into the substrate processing apparatus 1000. According to one embodiment, the loading unit 100 is configured in conformity with a mechanical device interface standard (IPC-SMEMA-9851) of SMEMA (Surface Mount Equipment Manufacturers Association).

In the illustrated embodiment, a transfer mechanism of the loading unit 100 includes a plurality of transfer rollers 202 and a plurality of roller shafts 204 which the transfer rollers 202 are mounted to. In the embodiment shown in FIG. 1, three transfer rollers 202 are mounted to each roller shaft 204. The substrate WF is placed on the transfer rollers 202 and is transferred by rotation of the transfer rollers 202. The mounting positions of the transfer rollers 202 on the roller shaft 204 may be any positions that enable the substrate WF to be transferred stably. The transfer rollers 202, however, come into contact with the substrate WF and are thus to be placed at such positions that the transfer rollers 202 come into contact with problem-free areas of the substrate WF as an object to be processed, which cause no problem by the contact. According to one embodiment, the transfer rollers 202 of the loading unit 100 may be made of a conductive polymer. According to one embodiment, the transfer rollers 202 are electrically grounded via the roller shaft 204 and the like. This aims to prevent the substrate WF from being charged and damaged. According to one embodiment, the loading unit 100 may be provided with an ionizer (not shown) to prevent the substrate WF from being charged.

### <Transfer Unit>

The substrate processing apparatus 1000 shown in FIG. 1 is provided with the two transfer units 200A and 200B. The two transfer units 200A and 200B have identical configurations and are collectively described below as the transfer unit 200.

The illustrated transfer unit 200 includes a plurality of transfer rollers 202 configured to transfer the substrate WF. Rotating the transfer rollers 202 causes the substrate WF on the transfer rollers 202 to be transferred in a predetermined direction. The transfer rollers 202 of the transfer unit 200 may be made of a conductive polymer or may be made of a non-conductive polymer. The transfer rollers 202 are driven by a non-illustrated motor. The substrate WF is transferred to a substrate delivery position by the transfer rollers 202.

According to one embodiment, the transfer unit 200 includes a cleaning nozzle 284. The cleaning nozzle 284 is connected with a non-illustrated supply source of a cleaning fluid. The cleaning nozzle 284 is configured to supply the cleaning fluid to the substrate WF that is transferred by the transfer rollers 202.

### <Polishing Unit>

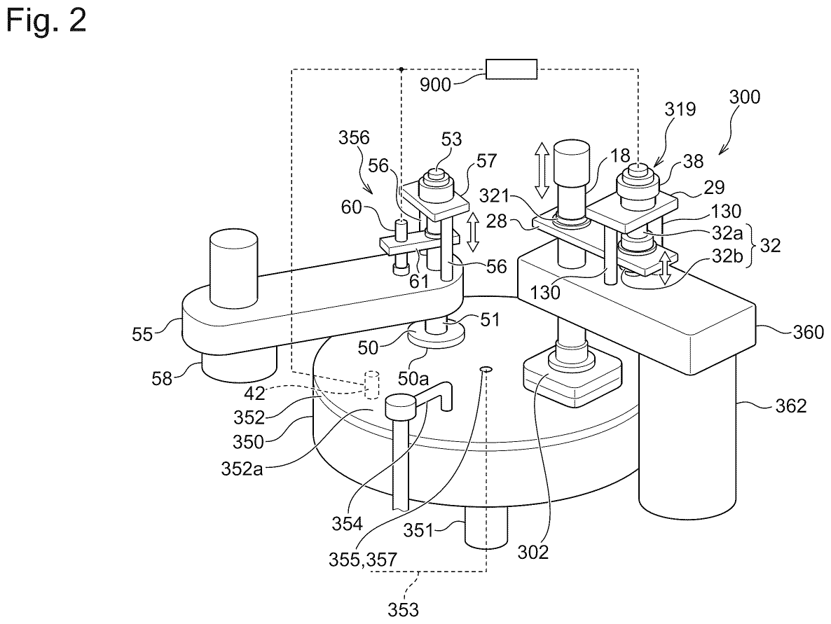

FIG. 2 is a perspective view schematically illustrating the configuration of the polishing unit 300 according to one embodiment. The substrate processing apparatus 1000 shown in FIG. 1 is provided with the two polishing units 300A and 300B. The two polishing units 300A and 300B have identical configurations and are collectively described below as the polishing unit 300.

As shown in FIG. 2, the polishing unit 300 includes a polishing table 350; and a top ring 302 that forms a polishing head configured to keep a substrate as an object to be polished and to press (to push) the substrate against a polishing surface on the polishing table 350. The polishing table 350 is connected with a polishing table rotating motor (not shown) placed below the polishing table 350 via a table shaft 351 and is configured to be rotatable about the table shaft 351. A polishing pad 352 is attached to an upper face of the polishing table 350, and a surface 352a of the polishing pad 352 forms the polishing surface serving to polish the substrate. According to one embodiment, the polishing pad 352 may be attached via a layer that facilitates peel-off from the polishing table 350. This layer may be, for example, a silicone layer or a fluororesin layer and may be that described in, for example, Japanese Unexamined Patent Publication No. 2014-176950 or the like. The entire disclosure of Japanese Unexamined Patent Publication No. 2014-176950 including the specification, claims, drawings and abstract is incorporated herein by reference in its entirety.

A polishing solution supply nozzle 354 is provided above the polishing table 350. This polishing solution supply nozzle 354 serves to supply a polishing solution onto the polishing pad 352 on the polishing table 350. As shown in FIG. 2, a passage 353 configured to supply the polishing solution is provided in the polishing table 350 and the table shaft 351. The passage 353 communicates with an opening 355 on the surface of the polishing table 350. A through hole 357 is formed in the polishing pad 352 at a position corresponding to the opening 355 of the polishing table 350. The polishing solution passing through the passage 353 is supplied from the opening 355 of the polishing table 350 and the through hole 357 of the polishing pad 352 to the surface of the polishing pad 352. The opening 355 of the polishing table 350 and the through hole 357 of the polishing pad 352 may be only one or may be plural. The position of the opening 355 of the polishing table 350 and of the through hole 357 of the polishing pad 352 may be any position but is placed in the vicinity of the center of the polishing table 350 according to one embodiment.

Although not being shown in FIG. 2, according to one embodiment, the polishing unit 300 is provided with an atomizer 358 (shown in FIG. 1) configured to spray a liquid or a mixed fluid of a liquid and a gas toward the polishing pad 352. The liquid sprayed from the atomizer 358 is, for example, pure water, and the gas is, for example, nitrogen gas.

The top ring 302 (or more specifically, a base member 420 described later) is connected with a top ring shaft 18. This top ring shaft 18 is moved up and down relative to a swing arm 360 by a vertical motion mechanism 319. The vertical motion of this top ring shaft 18 moves up and down and positions the entire top ring 302 relative to the swing arm 360. The top ring shaft 18 is rotated by driving a non-illustrated top ring rotating motor. The rotation of the top ring shaft 18 causes the top ring 302 to rotate about the top ring shaft 18.

The top ring 302 is configured to keep a substrate WF in a rectangular shape under a lower face thereof. The substrate WF may be a CCL (Copper Clad Laminate) substrate, a PCB (Printed Circuit Board) substrate, a photomask substrate, a display panel or any other rectangular substrate. A certain type of substrate has a plurality of wiring units formed thereon, and each of the plurality of wiring units has a wiring pattern. A die of an IC chip and the like may be mounted on each of the plurality of wiring units of the substrate which has been subjected to a polishing process. The swing arm 360 is configured to be turnable around a spindle 362. Turning of the swing arm 360 enables the top ring 302 to be moved between the substrate delivery position of the transfer unit 200 described above and a position above the polishing table 350. The downward motion of the top ring shaft 18 moves down the top ring 302, so as to press the substrate WF against the surface (polishing surface) 352a of the polishing pad 352. In this process, the top ring 302 and the polishing table 350 are respectively rotated, and the polishing solution is supplied onto the polishing pad 352 from the polishing solution supply nozzle 354 provided above the polishing table 350 and/or from the opening 355 provided in the polishing table 350. This series of operation presses the substrate WF against the polishing surface 352 of the polishing pad 352 and polishes the surface of the substrate WF. In the course of polishing the substrate WF, the swing arm 360 may be fixed or may be swung, such that the top ring 302 passes through the center of the polishing pad 352 (i.e., such that the top ring 302 covers the through hole 357 of the polishing pad 352).

The vertical motion mechanism 319 configured to move up and down the top ring shaft 18 and the top ring 302 includes a bridge 28 configured to support the top ring shaft 18 in a rotatable manner via a bearing 321; a ball screw 32 attached to the bridge 28; a support table 29 supported by supporting columns 130; and an AC servo motor 38 provided on the support table 29. The support table 29 configured to support the servo motor 38 is fixed to the swing arm 360 via the supporting columns 130.

The ball screw 32 includes a threaded shaft 32a connected with the servo motor 38; and a nut 32b which this threaded shaft 32a is screwed into. The top ring shaft 18 is moved up and down integrally with the bridge 28. Driving the servo motor 38 accordingly moves up and down the bridge 28 via the ball screw 32 and thereby moves up and down the top ring shaft 18 and the top ring 302.

The polishing unit 300 according to one embodiment includes a dressing unit 356 configured to dress the polishing surface 352a of the polishing pad 352. This dressing unit 356 includes a dresser 50 configured to come into sliding contact with the polishing surface 352a; a dresser shaft 51 which the dresser 50 is connected with; an air cylinder 53 provided at an upper end of the dresser shaft 51; and a swing arm 55 configured to support the dresser shaft 51 in a rotatable manner. A lower portion of the dresser 50 is configured by a dressing member 50a, and needle-shaped diamond particles adhere to a lower face of this dressing member 50a. The air cylinder 53 is placed on a support table 57 supported by supporting columns 56. These supporting columns 56 are fixed to the swing arm 55.

The swing arm 55 is driven by a non-illustrated motor and is configured to turn around a spindle 58. The dresser shaft 51 is rotated by driving a non-illustrated motor. The rotation of this dresser shaft 51 causes the dresser 50 to rotate about the dresser shaft 51. The air cylinder 53 moves up and down the dresser 50 via the dresser shaft 51, so as to press the dresser 50 against the polishing surface 352a of the polishing pad 352 by a predetermined pressing force. In the polishing device of this embodiment, this dresser 50 is used to measure an abrasion loss of the polishing pad 352. The dressing unit 356 is accordingly provided with a displacement sensor 60 configured to measure a displacement of the dresser 50. This displacement sensor 60 configures an abrasion loss detection unit configured to detect the abrasion loss of the polishing pad 352 and is provided on an upper face of the swing arm 55. A target plate 61 is fastened to the dresser shaft 51 and is moved up and down along with the vertical motion of the dresser 50. The displacement sensor 60 is placed such as to be inserted in this target plate 61 and is configured to measure the displacement of the dresser 50 by measuring a displacement of the target plate 61. The displacement sensor 60 may be any type of sensor, for example, a linear scale, a laser sensor, an ultrasonic sensor, or an eddy current sensor. The displacement sensor 60 and the target plate 61 may, however, be omitted.

Dressing of the polishing surface 352a of the polishing pad 352 is performed as described below. The dresser 50 is pressed against the polishing surface 352a by the air cylinder 53, and at the same time, pure water is supplied to the polishing surface 352a from a non-illustrated pure water supply nozzle. In place of or in addition to the supply of pure water from the non-illustrated pure water supply nozzle, pure water may be supplied to the polishing surface 352a by changing over the passage 353 and/or the polishing solution supply nozzle 354 from the supply of the polishing solution to the supply of pure water. In this state, the dresser 50 is rotated about the dresser shaft 51, and the swing arm 55 is swung on the polishing surface 352a, so that the lower face (with the diamond particles) of the dressing member 50a is brought into sliding contact with the rotating polishing surface 352a. This series of operation causes the polishing pad 352 to be scraped off by the dresser 50 and thereby dresses the polishing surface 352a.

The polishing unit 300 is further provided with a film thickness sensor 42 configured to measure film thicknesses of the substrate WF on the polishing surface 352a. The film thickness sensor 42 is configured to generate film thickness index values that directly or indirectly indicate the film thicknesses of the substrate WF. This film thickness index value is varied according to the film thickness of the substrate WF. The film thickness index value may be a value indicating the film thickness itself of the substrate WF or may be a physical amount or a signal value prior to conversion into the film thickness.

Examples of the film thickness sensor 42 include an eddy current sensor and an optical film thickness sensor. The film thickness sensor 42 is placed in the polishing table 350 and is rotated integrally with the polishing table 350. More specifically, the film thickness sensor 42 is configured to pass across the substrate WF on the polishing surface 352 at every rotation of the polishing table 350 and to measure film thicknesses at a plurality of measurement points of the substrate WF. The film thicknesses at the plurality of measurement points are output as the film thickness index values from the film thickness sensor 42 to the controller 900. The controller 900 is configured to control the operation of the top ring 302, based on the film thickness index values.

The controller 900 is configured to generate a film thickness profile of the substrate WF from the film thickness index values output from the film thickness sensor 42. The film thickness profile of the substrate WF is a distribution of the film thickness index values. The controller 900 controls the operation of the top ring 302 such as to eliminate a difference between a current film thickness profile of the substrate WF obtained and a target film thickness profile. The target film thickness profile of the substrate WF is stored in advance in the storage device 900b of the controller 900. Examples of the current film thickness profile of the substrate WF include an initial film thickness profile of the substrate WF prior to polishing in the substrate processing apparatus 1000 (the polishing unit 300) shown in FIG. 1 and a film thickness profile generated from the film thickness index values output from the film thickness sensor 42 in the process of polishing the substrate WF in the substrate processing apparatus 1000 shown in FIG. 1. The initial film thickness profile is generated, for example, from measured film thickness values obtained by a non-illustrated stand-alone film thickness measurement device or from measured film thickness values obtained by another substrate processing apparatus 1000 provided with a film thickness sensor. The initial film thickness profile is stored in the storage device 900b of the controller 900.

### <Drying Unit>

The drying unit 500 is a device configured to dry the substrate WF. In the substrate processing apparatus 1000 shown in FIG. 1, the drying unit 500 is configured to dry the substrate WF that is polished by the polishing unit 300 and is subsequently cleaned by a cleaning portion of the transfer unit 200. As shown in FIG. 1, the drying unit 50) is placed downstream of the transfer unit 200. The drying unit 500 includes nozzles 530 configured to spray a gas toward the substrate WF transferred on the transfer rollers 202. The gas may be, for example, the compressed air or nitrogen. Water droplets on the transferred substrate WF are blown off by the drying unit 500, so that the substrate WF is dried.

### <Unloading Unit>

The unloading unit 600 is a unit configured to carry the substrate WF that has been processed by polishing, cleaning and the like, out of the substrate processing apparatus 1000. In the substrate processing apparatus 1000 shown in FIG. 1, the unloading unit 600 receives the substrate that has been dried by the drying unit 500. As shown in FIG. 1, the unloading unit 600 is placed downstream of the drying unit 500. According to one embodiment, the unloading unit 600 is configured in conformity with a mechanical device interface standard (IPC-SMEMA-9851) of SMEMA (Surface Mount Equipment Manufacturers Association).

### <Top Ring>

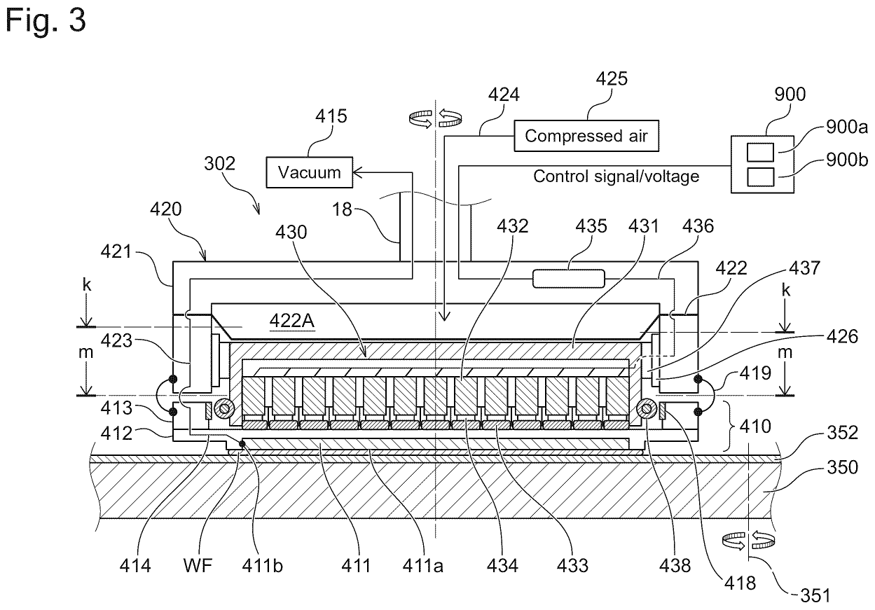

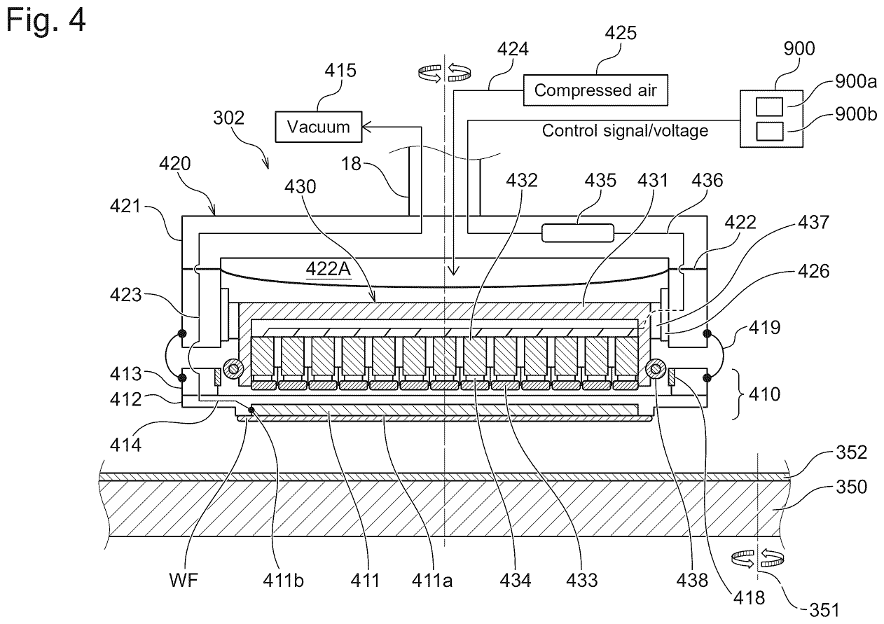

The following describes the top ring 302 in the polishing unit 300 according to one embodiment. FIG. 3 and FIG. 4 are sectional views schematically illustrating the top ring 302 according to one embodiment. FIG. 3 illustrates a sectional view of the top ring 302 when the substrate WF is brought into contact with the polishing pad 352, and a membrane 422 and piezoelectric elements 432 are in a pressurized state. FIG. 4 illustrates a sectional view of the top ring 302 when the substrate WF is not brought into contact with the polishing pad 352, and the membrane 422 and the piezoelectric elements 432 are in a non-pressurized state.

The top ring 302 includes a substrate suction member 410, a base member 420; and a piezoelectric element member 430 placed between the substrate suction member 410 and the base member 420. The substrate suction member 410, the base member 420 and the piezoelectric element member 430 are configured to be mutually slidable along a vertical direction. The piezoelectric element member 430 is slidable along the vertical direction relative to the base member 420 and the substrate suction member 410.

The substrate suction member 410 is placed below the base member 420 and the piezoelectric element member 430, and includes a porous member 411 and a shielding member 412 which the porous member 411 is attached to. The porous member 411 may be any member configured to vacuum suck the substrate WF by vacuuming using a decompression unit (vacuum source) 415 and may be configured by a porous resin material that has a large number of pores formed in a resin material, such as PE (polyethylene). PP (polypropylene). PTFE (polytetrafluoroethylene) or PVC (polyvinyl chloride). The porous member 411 may be configured by a ceramic material with a large number of pores formed therein. According to the embodiment, the porous member 411 is formed in a plate-like shape and includes a substrate suction face 411a configured to suck the substrate WF and a decompression portion 411b configured to communicate with the decompression unit (vacuum source) 415. Depressurization of the porous member 411 by the decompression unit (vacuum source) 415 causes the substrate WF to be sucked and held by the porous member 411.

The shielding member 412 may be any gastight member configured to block the flow of a gas and may be configured by a resin plate of a relatively soft resin, such as PE (polyethylene), PP (polypropylene), PTFE (polytetrafluoroethylene) or PVC (polyvinyl chloride). According to the embodiment, the shielding member 412 is formed to shield an opposite face of the porous member 411 that is opposite to the substrate suction face 411a, as well as a side face of the porous member 411. The shielding member 412 includes a vacuum hole 414 formed to communicate with the porous member 411. The decompression portion 411b is provided at a position where the vacuum hole 414 is formed. According to the embodiment, the vacuum hole 414 is formed in the shielding member 412 such as to communicate with the side face of the porous member 411, and the decompression portion 411b is provided in the side face of the porous member 411. One end of the vacuum hole 414 is connected with the side face of the porous member 411, and the other end of the vacuum hole 414 is connected with the decompression unit 415 via a suction path 423.

Providing the shielding member 412 enables a negative pressure to be generated efficiently on the substrate suction face 411a when the porous member 411 is vacuumed by the decompression unit (vacuum source) 415. This configuration enables the substrate WF to be certainly sucked to the substrate suction member 410 and thereby does not need to provide a retainer member around the substrate WF with a view to preventing the substrate WF from being popped out (slipped out) during polishing. This configuration also prevents the substrate WF or the top ring 302 from being brought into contact with the retainer member and being damaged during polishing.

The substrate suction member 410 includes a frame member 413 provided on the shielding member 412 to surround the circumference of at least part of the piezoelectric element member 430. The frame member 413 is provided in a frame-like shape on an outer peripheral portion of an upper face of the shielding member 412. The substrate suction member 410 is placed such that a motion of the substrate suction member 410 in the vertical direction is guided relative to the piezoelectric element member 430 and thereby relative to the base member 420 by means of support rollers 438 provided around the piezoelectric element member 430. As shown in FIG. 6, support pads 418 are provided on an inner side face of the frame member 413 corresponding to the respective support rollers 438. The configuration that causes the support pads 418 to be brought into contact with and guided by the support rollers 438 guides the motion of the substrate suction member 410 in the vertical direction relative to the piezoelectric element member 430. The support pad 418 may be provided to be used in common by a plurality of support rollers 438. The substrate suction member 410 is mounted to the piezoelectric element member 430 such as to be slightly movable relative to the piezoelectric element member 430 in a planar direction that is parallel to the polishing surface of the polishing pad 352. The frame member 413 is further provided with stoppers 413A (shown in FIG. 6) corresponding to four corners of the piezoelectric element member 430 to limit a downward motion of the substrate suction member 410.

The top ring 302 further includes an outer peripheral band 419 configured to connect an outer side face of a base body 421 of the base member 420 with an outer side face of the frame member 413 of the substrate suction member 410. The outer peripheral band 419 is provided to surround the whole circumference of the top ring 302. The outer peripheral band 419 serves to allow for a displacement of the substrate suction member 410 relative to the base member 420 and to prevent a polishing solution or the like from entering a space (inner space) between the substrate suction member 410 and the base member 420. In this illustrated example, a recess of the base member 420 that is open downward and a recess of the substrate suction member 410 that is open upward forms the inner space.

The base member 420 includes a base body 421 connected with the top ring shaft 18; and a membrane (elastic membrane) 422 attached to the base body 421 to form a compression chamber 422A. The membrane (elastic membrane) 422 may be made of, for example, silicone rubber. FKM or EPDM. The base body 421 has an inner space that is a recess open downward. The membrane 422 is placed above this inner space (on a bottom face side of the recess), and at least part of the piezoelectric element member 430 is placed below the membrane 422. The compression chamber 422A in the membrane 422 is connected with a compressed air supply source 425 via a flow path 424, and the membrane 422 is configured to be pressurized and expanded by the compressed air (pressurized fluid) from the compressed air supply source 425.

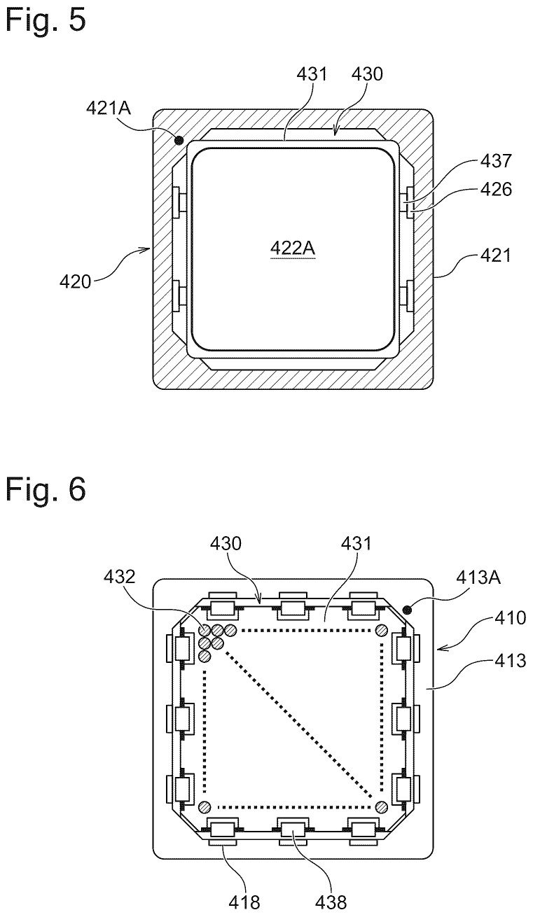

Linear guides 426 are provided on two opposed inner side faces of the base body 421 as shown in FIG. 3 and FIG. 5. In this illustrated example, two linear guides 426 are provided on each of the two opposed inner side faces as shown in FIG. 5. The linear guides 426 are engaged with linear guides 437 that are provided at corresponding positions of the piezoelectric element member 430, so as to guide a vertical motion of the piezoelectric element member 430 relative to the base member 420. For example, one of the linear guides 426 and the linear guides 437 may be rails, and the other may be sliding members that are to be engaged with the rails. This illustrated example provides the linear guides on only one pair of opposed inner side faces (i.e., only two inner side faces) out of four inner side faces of the base body 421. This facilitates smooth vertical motions of the base member 420 and the piezoelectric element member 430 relative to each other. The linear guides 426 may, however, be provided on all the inner side faces of the base body 421, unless there is any problem with regard to the vertical motions of the base member 420 and the piezoelectric element member 430 relative to each other.

The piezoelectric element member 430 includes a holder (holding body) 431 serving as a housing; a plurality of piezoelectric elements 432 placed inside of the holder 431; fluid bags 433 placed below the respective piezoelectric elements 432; and pressing force measurement devices 434 placed between the piezoelectric elements 432 and the fluid bags 433. Each of the pressing force measurement devices 434 may, however, be placed below the fluid bag 433 or at any other position, as long as a pressing force by each of the piezoelectric elements 432 (i.e., a pressing force of pressing the substrate WF against the polishing pad 352 at the position of each of the piezoelectric elements 432) is measurable.

The plurality of piezoelectric elements 432 are arranged, for example, in a matrix as shown in FIG. 6. The arrangement of the plurality of piezoelectric elements 432 is, however, not limited to the arrangement of FIG. 6 but may be any arrangement. It is preferable to use the piezoelectric elements 432 that respectively have substantially identical dimensions and characteristics. The characteristics of the piezoelectric element include, for example, an amount of stretch (stroke) to an applied voltage. The respective piezoelectric elements 432 are connected with a driving voltage application device 435 via electric wiring 436. In this illustrated example, the driving voltage application device 435 is built in the base body 421. The driving voltage application device 435 may, however, be placed outside of the top ring 302. The driving voltage application device 435 is configured to receive a control signal/voltage from the controller 900 and to supply a driving voltage corresponding to the control signal/voltage to the respective piezoelectric elements 432. Each of the piezoelectric elements 432 configures an individual actuator to apply a pressing force to each part (each area corresponding to the each piezoelectric element) of the substrate suction member 410 fully independently of each other.

The fluid bag 433 is a bag body member of low elasticity as a whole configured by keeping a fluid inside of a bag body that is made of a low elastic material (for example, silicon rubber, EPDM or FKM of high hardness, nylon film, polyethylene film, PET film, or a multi-layered film of the foregoing films; bag materials of commercially available emergency water bags are applicable) (i.e., the fluid bag 433 is a non-expandable bag body member/bag as a bag body member/bag that is deformable according to a change in shape of the fluid kept inside thereof but that is not expandable). In other words, the fluid bag 433 is a member configured to transmit a pressure generated by the piezoelectric element 432 to the substrate suction member 410 with no substantial expansion or contraction. In order to further suppress the expansion or contraction of the fluid bag 433, it is preferable that the fluid kept in the fluid bag 433 is a non-compressible fluid, for example, a liquid such as water or oil. Additionally, in order to ensure the liquid-filled fluid bag 433 as a member of low elasticity, it is preferable to fill the bag body of the fluid bag 433 with a sufficient amount of the liquid. The fluid may, however, be a gas, as long as the fluid bag 433 configures a member of low elasticity as a whole even the fluid kept in the fluid bag 433 is a gas. In this case, it is also preferable to fill the bag body of the fluid bag 433 with a sufficient amount of the gas. Using such fluid bags 433 of low elasticity enables the pressure to be uniformly transmitted to areas of the substrate suction member 410 immediately below the respective piezoelectric elements 432 and thereby uniformizes the pressure transmitted to the respective parts of the substrate suction member 410.

According to the embodiment, although thin partitions are provided between adjacent fluid bags 433 as shown in FIG. 3 and FIG. 4, the adjacent fluid bags 433 press the substrate-side (the substrate suction member 410) substantially tightly. Accordingly, the fluid bags 433 provided corresponding to the respective piezoelectric elements 432 enable the substrate suction member 410 and thereby the respective regions of the substrate WF to be pressed tightly (against the polishing pad 352). In other words, the fluid bags 433 serve to suppress or prevent uneven pressing by the respective piezoelectric elements 432.

When the driving voltage application device 435 applies a driving voltage to the plurality of piezoelectric elements 432, these piezoelectric elements 432 are stretched toward the fluid bags 433. The stretches of the piezoelectric elements 432 locally regulate the pressing force of the compression chamber 422A to press the substrate WF against the polishing pad 352. This suppresses or prevents an unevenness of pressing (a variation in pressing force) to press the substrate WF against the polishing pad 352 via the piezoelectric elements 432 by the compression chamber 422A. In the description below, the amount of stretch of the piezoelectric element may be referred to as stroke. This configuration enables the piezoelectric elements 432 under application of the driving voltage to regulate the pressing forces of pressing the substrate WF against the polishing pad 352 in the respective areas of the piezoelectric elements 432. Even when there is a variation in thickness in the “porous member 411, the substrate or the like” (the substrate WF, the porous member 411, and/or the shielding member 412), appropriate regulation of the strokes of the piezoelectric elements according to a variation in the thickness of the substrate WF or the like enables the respective regions (areas) of the substrate WT to be pressed against the polishing pad 352 with a uniform pressing force (i.e., uniformizes a surface pressure distribution) and thereby improves the in-plane uniformity of the polishing rate.

For example, when the substrate WF has a variation in thickness, pressing the respective regions (areas) of the substrate WF by uniform strokes by the compression chamber 422A causes a region of the larger thickness to be pressed against the polishing pad 352 by the greater pressing force, while causing a region of the smaller thickness to be pressed against the polishing pad 352 by the less pressing force. The configuration of the embodiment, on the other hand, regulates the stroke of the piezoelectric element in a region of the larger thickness (i.e., a region having an upward tendency of the polishing rate) to be relatively smaller than the stroke of the piezoelectric element in a region of the smaller thickness (i.e., a region having a downward tendency of the polishing rate). This uniformizes the pressing force of pressing the substrate WF against the polishing pad 352 by the compression chamber 422A between the respective regions (areas) of the substrate WF (i.e., uniformizes the surface pressure distribution). When there is a variation in thickness in the porous member 411 and/or the shielding member 412, appropriately regulating the strokes of the piezoelectric elements in the respective regions (areas) of the substrate WF similarly enables the pressing force of pressing the substrate WF against the polishing pad 352 by the compression chamber 422A to be uniformized between the respective regions (areas) of the substrate WF (i.e., uniformizes the surface pressure distribution). As described above, even when there is a variation in thickness in the substrate WF, the porous member 411, and/or the shielding member 412, the configuration of this embodiment appropriately regulates the strokes of the piezoelectric elements according to the variation in thickness in the substrate WF, the porous member 411, and/or the shielding member 412. This enables the respective regions (areas) of the substrate WF to be pressed against the polishing pad 352 with a uniform pressing force (i.e., uniformizes the surface pressure distribution) and thereby improves the in-plane uniformity of the polishing rate.

The pressing force measurement device 434 is a device configured to measure a pressing force (a force of pressing the substrate WF against the polishing pad 352) at the position of each piezoelectric element 432 and may be, for example, a pressure gauge. According to the embodiment, each of the pressing force measurement devices 434 is arranged in series with the piezoelectric element 432 and the fluid bag 433. More specifically, each of the pressing force measurement devices 434 is placed between the piezoelectric element 432 and the fluid bag 433. The pressing force measurement devices 434 of this arrangement enable the pressing forces of pressing the substrate WF against the polishing pad 352 to be measured separately with regard to the respective piezoelectric elements 432. The arrangement of the pressing force measurement devices 434 is, however, not limited to the arrangement of this embodiment shown in FIG. 3 and FIG. 4. The pressing force measurement devices 434 may be placed between the substrate suction member 410 and the fluid bags 433 or may be placed beside the fluid bags 433, as long as the pressing force measurement devices 434 enable the pressing forces of pressing the substrate WF against the polishing pad 352 to be measured separately with regard to the respective piezoelectric elements 432.

The pressing force measurement device 434 may be configured to convert the measured pressing force [N] into a pressure [Pa]. The pressing force measurement devices 434 may be, for example, a load cell or a piezoelectric sheet connected with a plurality of piezoelectric elements 432. The piezoelectric sheet is provided with a plurality of piezoelectric sensors and is configured to generate a voltage according to a force applied to the piezoelectric sheet and convert the value of the voltage into a force or a pressure.

As shown in FIG. 5, linear guides 437 are provided on two opposed outer side faces of the holder 431 of the piezoelectric element member 430. In this illustrated example, two linear guides 437 are provided on each of the opposed outer side faces of the holder 431. The linear guides 437 are engaged with the linear guides 426 of the base member 420, so as to guide the vertical motion of the piezoelectric element member 430 relative to the base member 420. Furthermore, as shown in FIG. 5, the base body 421 of the base member 420 is provided with four stoppers 421A corresponding to the four corners of the piezoelectric element member 430. These stoppers 421A serve to limit a downward motion of the piezoelectric element member 430.

As shown in FIG. 3 and FIG. 6, a plurality of support rollers 438 are provided on each outer side face of the holder 431. In this illustrated example, three support rollers 438 are arranged on each of the outer side faces of the holder 431. The number of the support rollers 438 may, however, be any arbitrary number. The support rollers 438 are provided below the linear guides 437 as shown in FIG. 3. The support pads 418 are provided on the inner side faces of the frame member 413 of the substrate suction member 410 corresponding to the respective support rollers 438. The configuration of rolling the respective support rollers 438 on the support pads 418 causes vertical motions of the substrate suction member 410 and the piezoelectric element member 430 to be guided relative to each other. Furthermore, as shown in FIG. 6, the frame member 413 of the substrate suction member 410 is provided with four stoppers 413A corresponding to the four corners of the piezoelectric element member 430. These stoppers 413A serve to limit a downward motion of the substrate suction member 410 relative to the piezoelectric element member 430.

In the state of FIG. 4, the stoppers 421A of the base member 420 limit a downward motion of the piezoelectric element member 430 relative to the base member 420, whereas the stoppers 413A of the substrate suction member 410 limit a downward motion of the substrate suction member 410 relative to the piezoelectric element member 430. According to a modification, stoppers (not shown) may be provided on inner side faces of the base body 421 to limit an upward motion of the piezoelectric element member 430 relative to the base members 420. These stoppers may be configured by, for example, protruding inner walls of the base body 421 toward above four corners of the holder 431 of the piezoelectric element member 430.

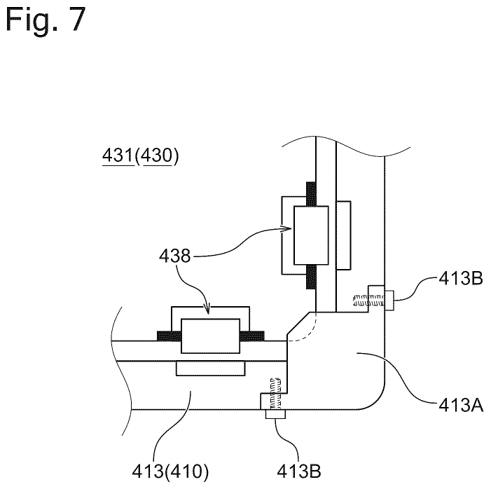

FIG. 7 illustrates a modification of the frame member of the substrate suction member. As shown in FIG. 7, the stoppers 413A of the frame member 413 may be configured to be detachable from the other part of the frame member 413. For example, the stopper 413A may be attached to the other part of the frame member 413 in a detachable manner by means of fastening members 413B, such as screws. This modified configuration enables the stoppers 413A to be detached and thereby enables the substrate suction member 410 to be readily demounted from the top ring 302. This facilitates maintenance, for example, replacement of the porous member as a consumable included in the substrate suction member. In the case where the substrate suction member 410 is demountable from the top ring 302 without detachment of all the four stoppers 413A, only part of the stoppers 413A may be configured to be detachable.

In the non-pressurized state of the top ring 302 shown in FIG. 4, the top ring 302 (the substrate WF) is not brought into contact with the polishing pad 352, and no driving voltage is applied to the piezoelectric elements 432 of the piezoelectric element member 430 (i.e., the piezoelectric elements are in a non-pressurized state). Furthermore, no sufficient amount of the compressed air is introduced into the compression chamber 422A, and the membrane 422 is not pressurized (i.e., the membrane 422 is in a non-pressurized state). The piezoelectric element member 430 is moved down relative to the base member 420 until the four corners of the holder 431 are engaged with the stoppers 421A of the base member 420 (shown in FIG. 5), whereas the substrate suction member 410 is moved down relative to the piezoelectric element member 430 until the stoppers 413A of the substrate suction member 410 (shown in FIG. 6) are engaged with the four corners of the piezoelectric element member 430.

In the pressurized state of the top ring 302 shown in FIG. 3, the substrate WF held by the top ring 302 is brought into contact with the polishing pad 352, and the pressurized fluid is introduced into the compression chamber 422A. The membrane 422 is accordingly expanded to press the piezoelectric element member 430 downward and to press the substrate suction member 410 downward via the plurality of piezoelectric elements 432 and the plurality of fluid bags 433. This causes the substrate WF to be pressed against the polishing pad 352. Furthermore, in this state, the strokes of the respective piezoelectric elements 432 are regulated, so as to regulate the pressing forces applied from the compression chamber 422A via the respective piezoelectric elements 432 to the respective parts (respective areas) of the substrate WF. Accordingly, in this state, while the substrate WF is pressed against the polishing pad 352 by the pressing force of the membrane 422, the pressing forces applied to the respective parts (respective areas) of the substrate WF are regulated by the plurality of piezoelectric elements 432. This accordingly uniformizes the surface pressure distribution of the pressing force by the compression chamber 422A to press the substrate WF against the polishing pad 352.

This configuration causes the substrate WF to be pressed against the polishing pad 352 by the pressing force of the membrane 422 applied to the entire area of the substrate WF, while causes the pressing forces applied to the respective areas of the substrate WF to be regulated by the strokes of the plurality of piezoelectric elements 432 corresponding to the respective areas of the substrate WF. Even when there is a variation in thickness in the porous member 411, the shielding member 412, and/or the substrate WF, this configuration enables the respective regions of the substrate WF to be pressed against the polishing pad 352 by the uniform force (i.e., uniformizes the surface pressure distribution). This improves the in-plane uniformity of the polishing rate (amount of polishing).

The film thickness control of the polishing process by the substrate processing apparatus 1000 described above may be performed, for example, by a procedure described below. The controller 900 computes a difference between the current film thickness profile of the substrate WF (i.e., a film thickness profile of the substrate WF generated from film thickness index values (index values that directly or indirectly indicate the film thicknesses of the substrate WF) output from the film thickness sensor 42 described above) and the target film thickness profile stored in advance in the storage device 900b and generates a distribution of target polishing amounts on a surface of the substrate WF to be polished. The controller 900 then determines command values of voltages that are to be applied to the piezoelectric elements 432, in order to achieve the target polishing amounts within a predetermined polishing time, based on the generated distribution of target polishing amounts. For example, the controller 900 generates a distribution of target polishing rates from the distribution of target polishing amounts and the predetermined polishing time, and determines command values of voltages that are expected to achieve the target polishing rates by referring to polishing rate correlation data. The polishing rate correlation data denotes data showing a relationship between the polishing rate and the command value of voltage.

The controller 900 sends the command values of voltages (control signals/voltages) to the driving voltage application device 435. The driving voltage application device 435 applies predetermined driving voltages to the piezoelectric elements 432 according to the command values of voltages (control signals/voltages) to regulate the film thickness profile of the substrate WF. During polishing of the substrate WF, the controller 900 regulates the film thickness profile, for example, at every fixed time intervals or at every rotation cycle of the polishing table 350.

In another example of the operation of the top ring 302, the controller 900 does not generate a distribution of target polishing amounts but determines command values of voltages to be applied to the piezoelectric elements 432, based on the current film thickness profile of the substrate WF obtained by the film thickness sensor 42. For example, when the target film thickness profile is a flat film thickness profile, in order to make the current film thickness profile closer to the flat film thickness profile, the controller 900 determines command values of voltages such as to apply a higher voltage that is higher by a predetermined change amount than the currently applied voltage, to each of the piezoelectric elements 432 corresponding to an area of large film thickness index values (i.e., index values that directly or indirectly indicate the film thicknesses of the substrate WF generated by the film thickness sensor 42 described above) and to apply a lower voltage that is lower by a predetermined change amount than the currently applied voltage, to each of the piezoelectric elements 432 corresponding to an area of small film thickness index values. These change amounts of voltages are set in advance as parameters in the controller 900.

### (Calibration)

The following describes calibration of the plurality of piezoelectric elements 432. The calibration of the piezoelectric elements 432 aims to adjust a relationship between the voltages (strokes) applied to the respective piezoelectric elements 432 and the uniformity of the surface pressure distribution when the substrate WF is pressed against the polishing pad 352 (by taking into account a difference in pressing force caused by an unevenness of, for example, the deformation hysteresis of the piezoelectric element 432, the placement height of the piezoelectric element 432, and the thickness of the substrate suction member 410 (the porous member 411 and the shielding member 412)).

### One Example of Calibration Method

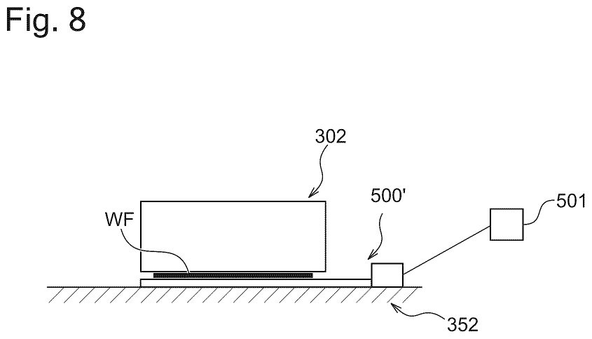

FIG. 8 is an explanatory diagram illustrating one example of a calibration method of the top ring. This calibration method places a surface pressure distribution measuring instrument 500′ on the polishing pad 352, places the top ring 302 with the substrate WF sucked thereto, on the surface pressure distribution measuring instrument 500′, and supplies the compressed air to the compression chamber 422A of the top ring 302 (shown in FIG. 3) so as to press the substrate WF against the polishing pad 352. According to a modification, in the state that the substrate WF is not held, the porous member 411 (shown in FIG. 3) may be pressed against the polishing pad 352. The surface pressure distribution measuring instrument 500′ may be a sheet-type pressure-sensitive sensor or tactile sensor. The surface pressure distribution measuring instrument 500′ is configured to include a pressure-sensitive portion having such dimensions as to cover the entire substrate WF and to have a surface pressure distribution measurement range that is larger than the dimensions of the substrate WF.

An operator uses a computer (PC) 501 connected with the surface pressure distribution measuring instrument 500′ to check a pressure distribution measured by the surface pressure distribution measuring instrument 500′ and to regulate the strokes (voltage values) of a plurality of piezoelectric elements 432, with a view to uniformizing the output (pressure distribution) of the surface pressure distribution measuring instrument 500′. A modification may use an artificial intelligence to performs an automatic calibration. The voltage values of the piezoelectric elements 432 obtained as described above are stored as calibration values in a storage device provided inside or outside of the computer (PC) 501. The controller 900 may be used as the computer 501.

This method enables a calibration of the piezoelectric elements 432 to be performed even when the top ring 302 is not provided with the pressing force measurement devices 434 (shown in FIG. 3).

Another method may determine the strokes of the piezoelectric elements, based on actual polishing results (a distribution of polishing rates) (Refer to Japanese Unexamined Patent Publication No. 2021-154421). The entire disclosure of Japanese Unexamined Patent Publication No. 2021-154421 including the specification, claims, drawings and abstract is incorporated herein by reference in its entirety.

### Another Example of Calibration Method

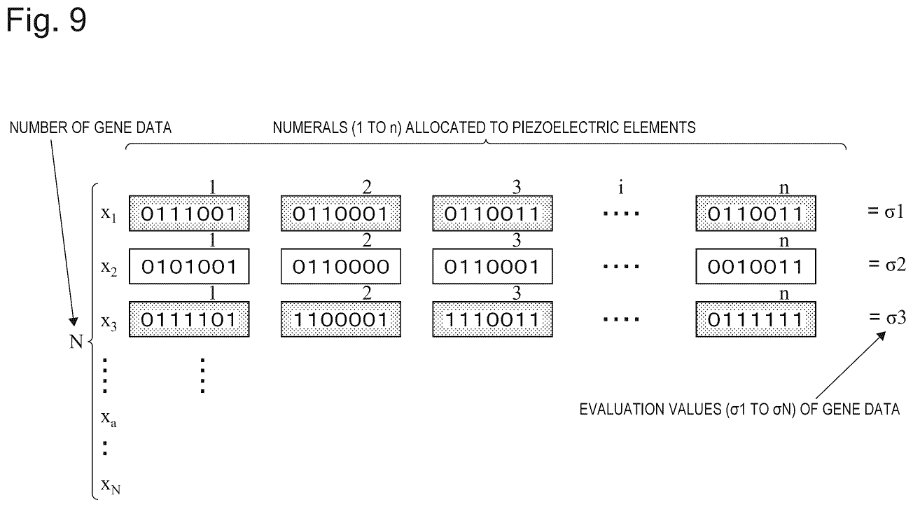

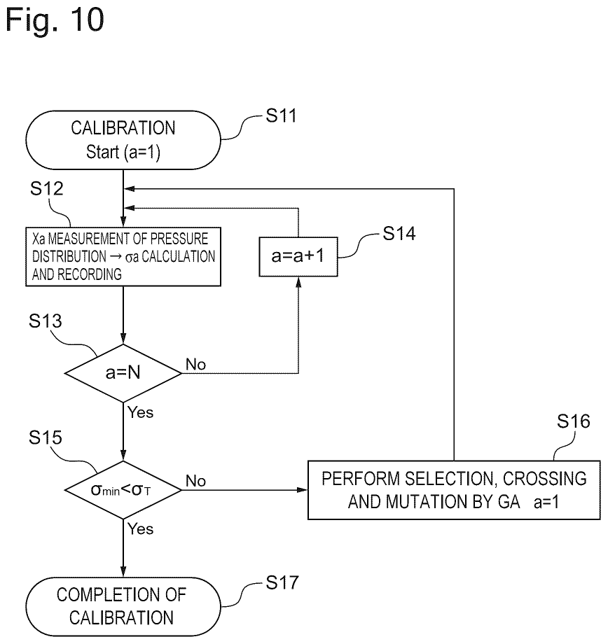

FIG. 9 is an explanatory diagram illustrating another example of the calibration method of the top ring. FIG. 10 is a flowchart showing a calibration of the piezoelectric elements. This example performs a calibration of the voltage values of the respective piezoelectric elements 432 according to a genetic algorithm (GA) by regarding a sequence including binary representations of the voltage values that are to be applied to the respective piezoelectric elements 432, as gene data.

For example, when a range of applied voltage to the piezoelectric elements 432 is a range of 0 to 5 [V], the number of partitions of the range of applied voltage is 2⁷=128. When a voltage value expressed in binary code is “1001011”, 1001011 (in binary) is equal to 75 (in decimal), and 75/128×5[V]≈2.93 [V]. Inversion operation of this calculation procedure enables the voltage of each piezoelectric element 432 to be binarized. For example, for binarization of a value V1 (in decimal), the procedure calculates V1 (in decimal)/5×128=V1′(a voltage value on the basis of the number of partitions, a value in decimal) and then expresses the decimal value V1′ in binary code. This procedure approximates the value V1′ to an integral value and subsequently binarizes this approximated integral value. For example, when V1=3 [V], the calculated value V1′=76.8. The procedure accordingly approximates the calculated value V1′=76.8≈77 and binarizes the approximated integral value 77 (expresses the approximated integral value in binary code). FIG. 9 shows an example of binarization of the voltage values of the respective piezoelectric elements 432. According to a modification, the value V1′ including a decimal part may be binarized.

In FIG. 9, xa denotes gene data (data corresponding to genes). In this example, N (≥2) gene data x1, x2, . . . , xa, . . . , xN are provided. Here n (≥2) denotes the total number of the piezoelectric elements 432 and i denotes a numeral allocated to identify each of the piezoelectric elements 432 (i-th piezoelectric element). For example, gene data x1 includes a voltage value “0111001” of a first piezoelectric element, a voltage value “0110001” of a second piezoelectric element, a voltage value “0110011” of a third piezoelectric element, . . . , and a voltage value “0110011” of an n-th piezoelectric element. The other gene data x1, x2, . . . , and xN are configured in a similar manner. In place of the voltage values to be applied to the piezoelectric elements, the strokes (displacements) of the piezoelectric elements may be binarized.

This calibration method generates a plurality of (N) gene data as shown in FIG. 9 and stores the generated gene data into a memory, such as the storage device 900b. The calibration method subsequently applies voltages to the respective piezoelectric elements 432, based on the gene data, obtains measured values of the pressing force measurement devices 434 when the substrate WF is pressed against the polishing pad 352 in the state of FIG. 3, and obtains evaluation function values (standard deviations) a (one a value is obtained for each gene data) calculated from the measured pressure values by Mathematical Expression 1 given below:

$$σ = \sqrt{\frac{1}{n} {\sum }_{i = 1}^{n} {( {P}_{i} - \overline{P} )}^{2}} \qquad [ Math . 1 ]$$

where σ denotes a standard deviation;
n denotes the number of piezoelectric elements;
i denotes a numeral allocated to each of the piezoelectric elements;
Pi denotes a measured pressure value of the pressing force measurement device with regard to an i-th piezoelectric element; and

P̅ [Math. 2]
denotes an average value of measured pressure values of the pressing force measurement devices with regard to the piezoelectric elements 1 to n.

In the case where all the standard deviations σ of the N gene data are equal to or greater than σT (an allowable value), the procedure performs selection, crossing and/or mutation with regard to the N gene data. In the case where the standard deviation a of any of the N gene data is less than σT, on the other hand, the procedure selects gene data having a minimum standard deviation a out of the gene data having the standard deviations of less than σT, as a calibration value, and stores the selected calibration value into the storage device (memory). Here σT denotes an allowable value of the standard deviation a and is set such that values of less than this value σT are acceptable for a surface pressure distribution.

The “selection” leaves gene data having superior set numbers (in this example, gene data having small standard deviations σ) out of the gene data 1 to N and replaces the remaining gene data with random gene data. This selects inferior gene data and leaves superior gene data. The “crossing” changes partial values (one value or multiple values) out of the values of the gene data x1, . . . , xN, with each other. For example, this operation changes a third bit value “0” of the voltage value of a first piezoelectric element in the gene data x2 and a fifth bit value “1” of the voltage value of a first piezoelectric element in the gene data x3 with each other. A part of sequential two or more numerical values may be changed with each other between different gene data. The “mutation” selects part of the values of the gene data x1, . . . , xN at random and inverts the selected part of values (from 0 to 1 or from 1 to 0).

When the standard deviations σ of all the N gene data are equal to or greater than σT, the procedure repeats the selection, the crossing and/or the mutation with regard to the N gene data and the measurement of the pressure distribution of the piezoelectric elements and the calculation of the standard deviation a with regard to each gene data, until detection of any gene data having the standard deviation a of less than σT.

Fully random gene data may be used as initial values of the N gene data, but a combination of voltages obtained in advance by experiment as a combination that is more likely to uniformize the surface pressure distribution may be used as part of the gene data. This latter configuration is expected to accelerate the convergence of the calibration (i.e., this is expected to reduce the number of measurements required for the calibration).

The following describes one exemplified flowchart of the calibration of the piezoelectric elements with reference to FIG. 10.

At step S11, the flow sets an identification number a of gene data to a value “1” and starts calibration.

At step S12, the flow applies voltage values of the a-th gene data to the respective piezoelectric elements, obtains the measured values of the pressing force measurement devices 434 (measures the pressure distribution/surface thickness distribution) with regard to the respective piezoelectric elements in the state of FIG. 3, calculates a standard deviation aa of the a-th gene data according to Mathematical Expression 1, and stores the calculated standard deviation aa into the storage device 900b or the like.

At step S13, the flow determines whether a is equal to N. When a is not equal to N, the flow increments a=a+1 at step S14 and repeats the processing of and after step S12. When a is equal to N, on the other hand, the flow proceeds to step S15. In other words, the flow repeats the processing of steps S12 to S14 until the pressure distributions with regard to all the N gene data are measured and the standard deviations σ1, . . . , σN with regard to all the N gene data are calculated.

At step S15, the flow determines whether a minimum standard deviation amin, out of the standard deviations σ1, . . . , σN of the N gene data, is less than the allowable value σT. A modified flow may employ any other arbitrary method to determine whether there is any gene data having the standard deviation a of less than σT out of the standard deviations σ1, . . . , σN of the N gene data. In this case, at step S17, the flow may select a minimum standard deviation or any arbitrary standard deviation out of standard deviations σa (a=1, . . . , N) of less than σT, as the calibration value.

When the standard deviation amin is equal to or greater than the allowable value σT at step S15, the flow performs an operation of the selection, the crossing, and/or the mutation with regard to the N gene data x1, . . . , xN, so as to generate new N gene data, x1, . . . , xN at step S16. The flow sets a=1 again and repeats the processing of and after S12 with regard to the newly generated N gene data x1, . . . , xN.

When the standard deviation amin is less than the allowable value σT at step S15, the flow proceeds to step S17. The flow stores gene data (calibration value) corresponding to the standard deviation amin of less than the allowable value σT, into the storage device 900b or the like and completes the calibration at step S17. In place of storing the gene data as the binary data into the storage device 900b or the like, a modification may convert the voltage value (binary number) into a decimal number and store the voltage value in decimal code into the storage device 900b or the like.

### Other Embodiments

(1) The above embodiment describes the top ring provided with a plurality of piezoelectric elements. The piezoelectric elements may, however, be replaced by a plurality of another type of actuators configured to generate a plurality of pressing forces fully independently of each other. Available examples of the actuator configured as the plurality of actuators include a hydraulic actuator such as a hydraulic cylinder and motor; a pneumatic actuator such as a pneumatic motor and a pneumatic cylinder; an electric actuator such as an electric motor; a magnetostrictive actuator using a magnetostrictor; an electromagnetic actuator such as a linear motor; and a compact piston.

(2) The above embodiment describes the substrate in a rectangular shape. The configuration of the above embodiment may, however, be applicable to a top ring used for polishing a wafer in a circular shape.

(3) The above embodiment describes the configuration that the plurality of piezoelectric elements 432 serve to locally regulate the pressing forces of pressing the respective parts (respective areas) of the substrate WF against the polishing pad 352 by the compression chamber 422A (the membrane 422). One modification may, however, omit the compression chamber 422A (the membrane 422) but may be configured to adjust the height of the top ring 302 by means of the vertical motion mechanism 319, to keep the top ring 302 at such a height that the substrate WF is brought into contact with or is pressed against the polishing pad 352 with a small pressing force, to cause the respective parts (respective areas) of the substrate WF to be pressed by a plurality of the piezoelectric elements 432, and to regulate the pressing forces applied to the respective parts (respective areas) of the substrate WT.

Although several embodiments of the present invention have been described above, the embodiments of the invention described above are presented to facilitate understanding of the present invention, and do not limit the present invention. The present invention can be altered and improved without departing from the subject matter of the present invention, and it is needless to say that the present invention includes equivalents thereof. In addition, it is possible to arbitrarily combine or omit respective constituent elements described in the claims and the specification in a range where at least a part of the above-mentioned problem can be solved or a range where at least a part of the effect is exhibited.

According to one aspect of the present disclosure, there is disclosed a top ring configured to hold a substrate, comprising: a base member connected with a rotating shaft; a substrate suction member including a porous member that has a substrate suction face configured to suck the substrate thereon and a decompression portion configured to communicate with a decompression unit; and a first pressurization assembly placed between the base member and the substrate suction member and provided with a plurality of first pressurization units, which are placed on an opposite side of the substrate suction member that is opposite to the substrate suction face, wherein each of the first pressurization units is configured to apply a pressing force fully independently of each other to the substrate suction member. The plurality of first pressurization units configured to apply the pressing forces fully independently of each other are, for example, pressing members (such as piezoelectric elements) individually driven by independent actuators.

The configuration of the top ring of this aspect presses the substrate against a polishing pad via the porous member by the plurality of first pressurization units and enables the pressing forces of the respective first pressurization units to be regulated fully independently of each other/individually. Even when there is a variation in thickness in the porous member, a shielding member configured to support the porous member, and/or the substrate, this configuration enables the pressing forces of the respective first pressurization units to be individually regulated and thereby enables respective regions (areas) of the substrate to be pressed against the polishing pad with a uniform pressing force. This improves the in-plane uniformity of the polishing rate. As a result, this enables a layer to be polished on the substrate, to be polished by a more uniform polishing amount.

Furthermore, according to one aspect of the present disclosure, there is disclosed the top ring, wherein the first pressurization assembly may further comprise a holder configured to hold the plurality of first pressurization units, and the base member may further comprise a second pressurization unit configured to press an opposite side of the holder that is opposite to a side where the plurality of first pressurization units are placed, by a fluid pressure.

The configuration of this aspect regulates the pressing forces of the plurality of first pressurization units to press the respective regions of the substrate, while regulating the pressing force of the second pressurization unit to press the entire substrate. This configuration accordingly enables the respective regions of the substrate to be pressed against the polishing pad with a desired uniform pressing force. In other words, this configuration enables the pressing force of pressing the substrate against the polishing pad to be mainly generated by the second pressurization unit, and enables the plurality of first pressurization units (for example, a plurality of piezoelectric elements) to be used as means for regulating the pressing forces applied to the respective areas of the substrate (i.e., the means for uniformizing the surface pressure distribution). For example, this configuration controls the strokes of the respective piezoelectric elements, so as to regulate the pressing force applied to the respective areas of the substrate by the second pressurization unit and uniformize the surface pressure distribution over the entire area of the substrate.

Moreover, according to one aspect of the present disclosure, there is disclosed the top ring, wherein the first pressurization assembly may comprise a fluid bag of low elasticity provided on a substrate suction member-side of each of the first pressurization units. The fluid bag of low elasticity is configured by, for example, a non-expanded bag member made of a low elastic material and sufficiently filled with a fluid.

The configuration of this aspect causes the pressing forces applied from the respective first pressurization units to be transmitted to the porous member via the non-expanded fluid bags of low elasticity and thereby reduces a variation in pressing by the respective first pressurization units. As a result, this configuration enables an appropriate pressing force to be closely applied to the entire area of the substrate.

Furthermore, according to one aspect of the present disclosure, there is disclosed the top ring, wherein the fluid bag may be configured to keep a fluid therein.

The configuration of this aspect causes a liquid to be kept as the fluid and thereby readily configures a non-expanded fluid bag of low elasticity.

Moreover, according to one aspect of the present disclosure, there is disclosed the top ring, wherein the first pressurization assembly may be configured to be movable in a vertical direction relative to the base member and the substrate suction member.

The configuration of this aspect causes the first pressurization assembly to be moved relative to the base member and thereby enables an additional pressurization unit (a second pressurization unit) to be placed on the base member and to readily press the first pressurization assembly in a direction of the substrate. This configuration enables the pressing force of pressing the substrate against the polishing pad to be mainly generated by the second pressurization unit, and enables the plurality of first pressurization units (for example, a plurality of piezoelectric elements) to be used as means for regulating the pressing forces applied to the respective areas of the substrate (i.e., the means for uniformizing the surface pressure distribution). Even when there is a variation in thickness in the porous member, a shielding member configured to support the porous member, and/or the substrate, the configuration of allowing the first pressurization assembly to be moved relative to the substrate suction member enables the substrate suction member and the substrate to be pressed against the polishing pad readily with an appropriate pressing force by an additional pressurization unit (a second pressurization unit) via the first pressurization assembly. Furthermore, even in the case where the base member is located at a fixed position relative to the polishing pad and the substrate has a varying thickness, and/or in the case where abrasion of the polishing pad varies the height position of a substrate polishing surface, the configuration of allowing the first pressurization assembly to be moved relative to the substrate suction member enables the substrate to be pressed against the polishing pad uniformly and stably.

Furthermore, according to one aspect of the present disclosure, there is disclosed the top ring, wherein the base member and the substrate suction member may be connected with each other by an outer peripheral band configured to seal a clearance between the base member and the substrate suction member, and the first pressurization assembly may be sealed in a space surrounded by the base member, the substrate suction member and the outer peripheral band.

The configuration of this aspect enables the first pressurization assembly to be protected from a polishing solution (slurry) and the like.

Moreover, according to one aspect of the present disclosure, there is disclosed the top ring, wherein a linear guide mechanism may be provided between an inner side face of the base member and an outer side face of the first pressurization assembly to guide a relative motion of the base member and the first pressurization assembly relative to each other.

The configuration of this aspect enables the first pressurization assembly and the base member to be moved relative to each other (i.e., enables the first pressurization assembly to be moved relative to the base member), while maintaining an appropriate positional relationship between the first pressurization assembly and the base member.

Furthermore, according to one aspect of the present disclosure, there is disclosed the top ring, wherein the first pressurization assembly may have a rectangular shape in planar view, and the linear guide mechanism may be provided on only one pair of opposed outer side faces of the first pressurization assembly.

The configuration of this aspect facilitates the smooth relative motion between the first pressurization assembly and the base member.

Moreover, according to one aspect of the present disclosure, there is disclosed the top ring, wherein the first pressurization assembly may comprise a plurality of rollers provided along an outer circumference of the first pressurization assembly, and the plurality of rollers may be configured to guide a motion of the substrate suction member in the vertical direction relative to the first pressurization assembly.

The configuration of this aspect enables the first pressurization assembly and the substrate suction member to be moved relative to each other, while maintaining an appropriate positional relationship between the first pressurization assembly and the substrate suction member.

Furthermore, according to one aspect of the present disclosure, there is disclosed the top ring, wherein the base member may have a first stopper configured to limit a downward motion of the first pressurization assembly relative to the base member, and the substrate suction member may have a second stopper configured to limit a downward motion of the substrate suction member relative to the first pressurization assembly.

When the top ring is separated from the polishing pad and is lifted up, the configuration of this aspect prevents the respective parts of the top ring from colliding with each other, from being dropped off, or the like and ensures the appropriate operations of the top ring.

Moreover, according to one aspect of the present disclosure, there is disclosed the top ring, wherein the base member, the substrate suction member and the first pressurization assembly may have rectangular shapes in planar view, the first stoppers may be provided in the base member corresponding to four corners of the first pressurization assembly, and the second stoppers may be provided in the substrate suction member corresponding to the four corners of the first pressurization assembly.

When the respective members, i.e., the base member, the substrate suction member and the first pressurization assembly have rectangular shapes in planar view, the configuration of this aspect provides the first stoppers at four corners of the base member and provides the second stoppers at four corners of the substrate suction member. This simple configuration effectively limits a movable range of relative motions between the respective members.

Furthermore, according to one aspect of the present disclosure, there is disclosed the top ring, wherein part or all of the second stoppers may be configured to be detachable along with each corresponding corner of the substrate suction member, and in a state that part or all of the second stoppers are detached along with the each corresponding corner of the substrate suction member, the substrate suction member may be configured to be demountable from the first pressurization assembly.

The configuration of this aspect enables the substrate suction member to be demounted from the top ring by detaching part or all of the second stoppers and thereby facilitates demounting of the substrate suction member. This facilitates maintenance, for example, replacement of the porous member as a consumable included in the substrate suction member.

Furthermore, according to one aspect of the present disclosure, there is disclosed the top ring, wherein the substrate may comprise a substrate body and a plurality of wiring units placed on the substrate body, and each of the first pressurization units may have dimensions corresponding to dimensions of each of the wiring units. In some cases, an apparatus for processing a substrate may be used to polish a substrate with a plurality of wiring units formed thereon. In this type of substrate, each of the plurality of wiring units has a wiring pattern. A die of an IC chip and the like may be mounted on each of the plurality of wiring units of the substrate which have been subjected to a polishing process.

In the case where the substrate includes a plurality of wiring units, the configuration of this aspect enables each of the wiring units as a polishing object to be appropriately pressed by each of the first pressurization units. This configuration enables the wiring pattern of each wiring unit to be polished to a flat height.

Furthermore, according to one aspect of the present disclosure, there is disclosed the top ring, wherein the substrate may be a rectangular substrate.

The configuration of this aspect enables respective regions of a rectangular substrate, which are likely to have a large variation in thickness to be pressed against the polishing pad with a uniform pressing force and thereby to be polished at a uniform polishing rate.

Moreover, according to one aspect of the present disclosure, there is disclosed the top ring, wherein the first pressurization unit may be a piezoelectric element.

The configuration of this aspect uses piezoelectric elements as the first pressurization units. This compact and simple configuration enables the pressing forces applied to the respective regions of the substrate to be accurately controlled.

Furthermore, according to one aspect of the present disclosure, there is disclosed the top ring, wherein the second pressurization unit may be a membrane provided with a compression chamber.

The configuration of this aspect uses a membrane as the second pressurization unit. This compact and simple configuration enables the pressing force of pressing the entire substrate to be controlled accurately.

Furthermore, according to one aspect of the present disclosure, there is disclosed an apparatus for processing a substrate, comprising the top ring according to any one of the above aspects; a polishing table configured to hold a polishing pad which the substrate held by the top ring is pressed against; the decompression unit connected with the porous member; and a first control unit configured to control a pressing force applied by each of the first pressurization units.

The configuration of this aspect has the functions and the advantageous effects described above. More specifically, this configuration enables the pressing forces applied by the plurality of first pressurization units to be controlled by the first control unit and thereby enables the respective regions of the substrate to be pressed against the polishing pad with a uniform pressing force.

Moreover, according to one aspect of the present disclosure, there is provided the apparatus for polishing the substrate, wherein the first pressurization assembly may further comprise a holder configured to hold the plurality of first pressurization units, and the base member may further comprise a second pressurization unit configured to press an opposite side of the holder that is opposite to a side where the plurality of first pressurization units are placed, by a fluid pressure. The apparatus for polishing the substrate of this aspect may further comprise a second control unit configured to regulate a pressing force applied by the second pressurization unit.

The configuration of this aspect has the functions and the advantageous effects described above. More specifically, this configuration enables the pressing force applied by the second pressurization unit(s) to be controlled by the second control unit and thereby enables an appropriate pressing force to be applied to the entire substrate. This configuration enables the pressing force of pressing the substrate against the polishing pad to be mainly generated by the second pressurization unit, and enables the plurality of first pressurization units (for example, a plurality of piezoelectric elements) to be used as means for regulating the pressing forces applied to the respective areas of the substrate (i.e., the means for uniformizing the surface pressure distribution). For example, this configuration controls the strokes of the respective piezoelectric elements (the respective first pressurization units), so as to regulate the pressing force applied to the respective areas of the substrate by the second pressurization unit and uniformize the surface pressure distribution over the entire area of the substrate.

Furthermore, according to one aspect of the present disclosure, there is disclosed the apparatus for polishing the substrate, wherein the first control unit may be configured to regulate the pressing force applied by each of the first pressurization units, such as to make a film thickness distribution of the substrate close to a target film thickness distribution, based on a result of measurement of the film thickness distribution during polishing.

The configuration of this aspect regulates the pressing force applied by each of the first pressurization units, based on the result of measurement of the film thickness distribution during polishing and thereby makes the film thickness distribution of the substrate close to the target film thickness distribution. This configuration accordingly allows for accurate control of the film thickness distribution of the substrate.

Moreover, according to one aspect of the present disclosure, there is disclosed a method of performing calibration of a top ring provided with a plurality of piezoelectric elements by using a genetic algorithm. The method comprises: providing a plurality of gene data as sequence data which are a data array of binary numbers representing voltages to be supplied to the respective piezoelectric elements, actually supplying voltages corresponding to the plurality of gene data to the plurality of piezoelectric elements and measuring pressing forces applied by the respective piezoelectric elements; calculating a standard deviation of measured values of the pressing forces applied by the plurality of piezoelectric elements, with regard to each of the gene data; when a minimum standard deviation out of the standard deviations with regard to the plurality of gene data is equal to or greater than a predetermined allowable value, performing an operation of selection, crossing and/or mutation with regard to the plurality of gene data according to the genetic algorithm, so as to generate a new set of a plurality of gene data, and repeating the measuring the pressing forces applied by the plurality of piezoelectric elements and the calculating the standard deviation with regard to each of the gene data by using the new set of the plurality of gene data, until the minimum standard deviation out of the standard deviations with regard to the plurality of gene data becomes less than the predetermined allowable value; and when the minimum standard deviation out of the standard deviations with regard to the plurality of gene data becomes less than the predetermined allowable value, selecting gene data corresponding to the minimum standard deviation as a combination of voltages to be supplied to the plurality of piezoelectric elements.

The configuration of this aspect enables calibration of the plurality of piezoelectric elements to be performed simply and accurately.

Furthermore, according to one aspect of the present disclosure, there is disclosed a storage medium configured to store therein a program that causes a computer to perform a method of performing calibration of a top ring provided with a plurality of piezoelectric elements by using a genetic algorithm. The program causes the computer to perform: providing a plurality of gene data as sequence data which are a data array of binary numbers representing voltages to be supplied to the respective piezoelectric elements; actually supplying voltages corresponding to the plurality of gene data to the plurality of piezoelectric elements and measuring pressing forces applied by the respective piezoelectric elements; calculating a standard deviation of measured values of the pressing forces applied by the plurality of piezoelectric elements, with regard to each of the gene data; when a minimum standard deviation out of the standard deviations with regard to the plurality of gene data is equal to or greater than a predetermined allowable value, performing an operation of selection, crossing and/or mutation with regard to the plurality of gene data according to the genetic algorithm, so as to generate a new set of a plurality of gene data, and repeating the measuring the pressing forces applied by the plurality of piezoelectric elements and the calculating the standard deviation with regard to each of the gene data by using the new set of the plurality of gene data, until the minimum standard deviation out of the standard deviations with regard to the plurality of gene data becomes less than the predetermined allowable value; and when the minimum standard deviation out of the standard deviations with regard to the plurality of gene data becomes less than the predetermined allowable value, selecting gene data corresponding to the minimum standard deviation as a combination of voltages to be supplied to the plurality of piezoelectric elements. The storage medium may also be referred to as a memory medium or a storage device.

### REFERENCE SIGNS LIST

18 top ring shaft (rotating shaft)
300 polishing unit
302 top ring
350 polishing table
351 table shaft
352 polishing pad
410 substrate suction member
411 porous member
411a substrate suction face
411b decompression portion
412 shielding member
413 frame member
413A stopper
413B fastening member
414 vacuum hole
415 decompression unit
418 support pad
419 outer peripheral band
420 base member
421 base body
421A stopper
422 membrane (elastic membrane)
422A compression chamber
423 suction path
424 flow path
425 compressed air supply source
426 linear guide
430 piezoelectric element member
431 holder (holding body)
432 piezoelectric element
433 fluid bag
434 pressing force measurement device
435 driving voltage application device
436 electric wiring
437 linear guide
438 support roller
500′ surface pressure distribution measuring instrument
501 PC
900 controller
1000 substrate processing apparatus
WF substrate

1. A top ring configured to hold a substrate, comprising:
a base member connected with a rotating shaft;
a substrate suction member including a porous member that has a substrate suction face configured to suck the substrate thereon and a decompression portion configured to communicate with a decompression unit; and
a first pressurization assembly placed between the base member and the substrate suction member and provided with a plurality of first pressurization units, which are placed on an opposite side of the substrate suction member that is opposite to the substrate suction face, wherein each of the first pressurization units is configured to apply a pressing force fully independently of each other to the substrate suction member,
wherein the first pressurization assembly comprises a fluid bag of low elasticity provided on a substrate suction member-side of each of the first pressurization units.

2. The top ring according to claim 1,
wherein the first pressurization assembly further comprises a holder configured to hold the plurality of first pressurization units, and
the base member further comprises a second pressurization unit configured to press an opposite side of the holder that is opposite to a side where the plurality of first pressurization units are placed, by a fluid pressure.

3. (canceled)

4. The top ring according to claim 1,
wherein the fluid bag is configured to keep a fluid therein.

5. The top ring according to claim 1,
wherein the first pressurization assembly is configured to be movable in a vertical direction relative to the base member and the substrate suction member.

6. The top ring according to claim 5,
wherein the base member and the substrate suction member are connected with each other by an outer peripheral band configured to seal a clearance between the base member and the substrate suction member, and
the first pressurization assembly is sealed in a space surrounded by the base member, the substrate suction member and the outer peripheral band.

7. The top ring according to claim 5,
wherein a linear guide mechanism is provided between an inner side face of the base member and an outer side face of the first pressurization assembly to guide a relative motion of the base member and the first pressurization assembly relative to each other.

8. The top ring according to claim 7,
wherein the first pressurization assembly has a rectangular shape in planar view, and
the linear guide mechanism is provided on only one pair of opposed outer side faces of the first pressurization assembly.

9. The top ring according to claim 5,
wherein the first pressurization assembly comprises a plurality of rollers provided along an outer circumference of the first pressurization assembly, and
the plurality of rollers are configured to guide a motion of the substrate suction member in the vertical direction relative to the first pressurization assembly.

10. The top ring according to claim 1,
wherein the base member has a first stopper configured to limit a downward motion of the first pressurization assembly relative to the base member, and
the substrate suction member has a second stopper configured to limit a downward motion of the substrate suction member relative to the first pressurization assembly.

11. The top ring according to claim 10,
wherein the base member, the substrate suction member and the first pressurization assembly have rectangular shapes in planar view,
the first stoppers are provided in the base member corresponding to four corners of the first pressurization assembly, and
the second stoppers are provided in the substrate suction member corresponding to the four corners of the first pressurization assembly.

12. The top ring according to claim 11,
wherein part or all of the second stoppers are configured to be detachable along with each corresponding corner of the substrate suction member, and
in a state that part or all of the second stoppers are detached along with the each corresponding corner of the substrate suction member, the substrate suction member is configured to be demountable from the first pressurization assembly.

13. The top ring according to claim 1,
wherein the substrate comprises a substrate body and a plurality of wiring units placed on the substrate body, and
each of the first pressurization units has dimensions corresponding to dimensions of each of the wiring units.

14. The top ring according to claim 1,
wherein the substrate is a rectangular substrate.

15. The top ring according to claim 1,
wherein the first pressurization unit is a piezoelectric element.

16. The top ring according to claim 2,
wherein the second pressurization unit is a membrane provided with one or more compression chambers.

17. An apparatus for processing a substrate, comprising:
the top ring according to claim 1;
a polishing table configured to hold a polishing pad which the substrate held by the top ring is pressed against;
the decompression unit connected with the porous member; and
a first control unit configured to control a pressing force applied by each of the first pressurization units.

18. The apparatus for processing the substrate according to claim 17,
wherein the first pressurization assembly further comprises a holder configured to hold the plurality of first pressurization units, and
the base member further comprises a second pressurization unit configured to press an opposite side of the holder that is opposite to a side where the plurality of first pressurization units are placed, by a fluid pressure,
the apparatus for processing the substrate further comprising a second control unit configured to regulate a pressing force applied by the second pressurization unit.

19. The apparatus for processing the substrate according to claim 17,
wherein the first control unit is configured to regulate the pressing force applied by each of the first pressurization units, such as to make a film thickness distribution of the substrate close to a target film thickness distribution, based on a result of measurement of the film thickness distribution during polishing.

20. A method of performing calibration of the top ring according to claim 1 wherein the plurality of first pressurization units are a plurality of piezoelectric elements by using a genetic algorithm, the method comprising:
providing a plurality of gene data as sequence data which are a data array of binary numbers representing voltages to be supplied to the respective piezoelectric elements;
actually supplying voltages corresponding to the plurality of gene data to the plurality of piezoelectric elements and measuring pressing forces applied by the respective piezoelectric elements;
calculating a standard deviation of measured values of the pressing forces applied by the plurality of piezoelectric elements, with regard to each of the gene data;
when a minimum standard deviation out of the standard deviations with regard to the plurality of gene data is equal to or greater than a predetermined allowable value, performing an operation of selection, crossing and/or mutation with regard to the plurality of gene data according to the genetic algorithm, so as to generate a new set of a plurality of gene data, and repeating the measuring the pressing forces applied by the plurality of piezoelectric elements and the calculating the standard deviation with regard to each of the gene data by using the new set of the plurality of gene data, until the minimum standard deviation out of the standard deviations with regard to the plurality of gene data becomes less than the predetermined allowable value; and
when the minimum standard deviation out of the standard deviations with regard to the plurality of gene data becomes less than the predetermined allowable value, selecting gene data corresponding to the minimum standard deviation as a combination of voltages to be supplied to the plurality of piezoelectric elements.

21. A storage medium configured to store therein a program that causes a computer to perform a method of performing calibration of the top ring according to claim 1 wherein the plurality of first pressurization units are a plurality of piezoelectric elements by using a genetic algorithm, wherein the program causes the computer to perform:
providing a plurality of gene data as sequence data which are a data array of binary numbers representing voltages to be supplied to the respective piezoelectric elements;
actually supplying voltages corresponding to the plurality of gene data to the plurality of piezoelectric elements and measuring pressing forces applied by the respective piezoelectric elements;
calculating a standard deviation of measured values of the pressing forces applied by the plurality of piezoelectric elements, with regard to each of the gene data;
when a minimum standard deviation out of the standard deviations with regard to the plurality of gene data is equal to or greater than a predetermined allowable value, performing an operation of selection, crossing and/or mutation with regard to the plurality of gene data according to the genetic algorithm, so as to generate a new set of a plurality of gene data, and repeating the measuring the pressing forces applied by the plurality of piezoelectric elements and the calculating the standard deviation with regard to each of the gene data by using the new set of the plurality of gene data, until the minimum standard deviation out of the standard deviations with regard to the plurality of gene data becomes less than the predetermined allowable value; and
when the minimum standard deviation out of the standard deviations with regard to the plurality of gene data becomes less than the predetermined allowable value, selecting gene data corresponding to the minimum standard deviation as a combination of voltages to be supplied to the plurality of piezoelectric elements.
